(19) United States
(12) Patent Application Publication
(10) Pub. No.: US 2026/0231565 A1
(43) Pub. Date: Aug. 6, 2026

(54) FAST-SWITCHING INGAALP-BASED µLEDS FOR HIGH-SPEED DATA COMMUNICATION

(71) Applicant: ams-OSRAM International GmbH, Regensburg (DE)

(72) Inventors: Martin Hetzl, Painten (DE); Norwin von Malm, Nittendorf (DE)

(21) Appl. No.: 19/149,488

(22) PCT Filed: Jan. 18, 2024
(86) PCT No.: PCT/EP2024/051194

§ 371 Date: Jul. 18, 2025

(30) Foreign Application Priority Data
Jan. 23, 2023 (DE) 10 2023 101 569.9

(51) Int. Cl. H10H 20/819; H10H 20/01; H10H 20/824

(52) U.S. Cl. CPC H10H 20/819; H10H 20/013; H10H 20/824

(57) ABSTRACT

In an embodiment a μ-LED includes a semiconductor layer stack having a first charge transportation layer of a first doping type, a second charge transportation layer of a second doping type, and an active region arranged between the first and second charge transportation layers, wherein the semiconductor layer stack has a top surface as well as side surfaces adjacent to the top surface, wherein the side surfaces are inclined with respect to a normal of the top surface, and wherein the semiconductor layer stack is based on an aluminum gallium indium phosphide system, a regrowth layer covering the side surfaces, and a first contact element arranged on the first charge transportation layer and a second contact element electrically contacting the second charge transportation layer, wherein edge regions of the active region adjacent to the side surfaces are contaminated with at least one of oxygen, iron, silicon, magnesium, sulfur, tellurium, beryllium, or bor.

### CROSS-REFERENCE TO RELATED APPLICATIONS

This patent application is a national phase filing under section 371 of PCT/EP2024/051194, filed Jan. 18, 2024, which claims the priority of German patent application no. 10 2023 101 569.9, filed Jan. 23, 2023, each of which is incorporated herein by reference in its entirety.

### TECHNICAL FIELD

The present invention concerns a μ-LED for use as a means for optical data communication, as well as a method for manufacturing the μ-LED.

### BACKGROUND

Today's Internet relies on large data centres. However, their high-power consumption poses problems to ensure their operation with purely sustainable energy sources. Most of the power is consumed not for computations, but for data transmission over short distances (<<10 m) : CPU to GPU, server to server, rack to rack.

Currently, short-range data communication is either done electrically, mainly by copper (Cu) or aluminium (Al) feed lines and wires (intra-chip or within mainboard), or optically by the combination of near infrared (NIR) vertical-cavity surface-emitting lasers (VCSEL) with optical fibres. The metals however cause electrical power losses due to their specific resistance and the VCSELs on the other hand need a certain threshold current (Iₜₕ) to start laser emission, typically in the mA regime. Together with the necessary forward voltage this threshold current Iₜₕ defines a dissipated (electrical) power of some mW.

To reduce the power for optical short range data transmission there are activities on using blue Indium Gallium Nitride (InGaN) μ-LEDs to tackle the challenge of high power consumption. InGaN μ-LEDs namely have the advantage of a possible operation with low currents (1-500 μA per pixel), which is many factors lower as for lasers, e.g. VCSELs, and they don't need a (lasing-)threshold, which needs to be passed. In addition, InGaN μ-LEDs have a small footprint (<5 μm possible) and can be transferred to backplane wafers by common display technologies, thus a high parallelization while transferring the μ-LEDs can be achieved further reducing the power consumption while manufacturing the hardware.

InGaN μ-LEDs on the other hand are however disadvantageous for a data transfer via a multi-core fibre, as the blue light emitted with the InGaN μ-LEDs is absorbed more and more with increasing length of the fibre as well as silicon (Si) based detectors may only provide a poor sensitivity to blue light. On optical data transmission using InGaN μ-LEDs is thus limited to “very short” distances. When increasing the amount of Indium in the InGaN, the light emitted by the InGaN μ-LEDs could be shifted to longer wavelengths (e.g. at green colour), which would reduce the absorption within the fibre and Si based detectors would comprise a higher sensitivity for light with longer wavelengths (e.g. at green colour). However, increasing the indium in the InGaN comes with a reduce switching speed of InGaN-based μLED, due to increasing piezo-field (strain) with within the μ-LEDs.

### SUMMARY

Embodiments provide an optoelectronic device that can be used for optical data communication with a reduced energy consumption while maintaining or even increasing the data transmission rate to be achieved or the switching time required for this.

According to an aspect of the present invention, a μ-LED is provided. The μ-LED comprises a semiconductor layer stack having a first charge transportation layer of a first doping type, a second charge transportation layer of a second doping type, and an active region arranged between the first and the second charge transportation layer. The semiconductor layer stack further comprises a top surface as well as side surfaces adjacent to the top surface, wherein the side surfaces are inclined with respect to a normal of the top surface. This inclination can in particular result of a first etching step of an epi structure on a wafer, to separate individual islands of the active region, which later then are each part of one optoelectronic device.

Further, the semiconductor layer stack is based on an aluminum gallium indium phosphide (InGaAlP) system. In addition, the μ-LED comprises a regrowth layer covering the side surfaces as well as a first contact element arranged on the first charge transportation layer and a second contact element electrically contacting the second charge transportation layer.

Edge regions of the active region adjacent to the side surfaces are contaminated with at least one of: oxygen; iron; silicon; magnesium; sulfur; tellurium; beryllium; and bor.

The idea of this invention is based on using InGaAlP μ-LEDs instead of InGaN. Initially, the InGaAlP material system would be less suitable for high-speed data communication applications, since InGaAlP LEDs are usually characterized by a slow switching-speed due to high charge carrier lifetimes/diffusion lengths as well as inefficient quantum efficiencies (internal and external), when downsizing to smaller LED sizes (μ-LEDs). The downsizing and thus the reduction of size of the μ-LEDs however has the effect that at the same time the charge carrier diffusion length/mean-free path and, thus, the charge carrier lifetime is reduced resulting in a faster switch off time of the μ-LEDs and thus possible faster switching speeds.

At the same time the inefficient quantum efficiency can be tackled by use of regrowth and/or quantum-well-intermixing (QWI) to increase the radiative recombination efficiency. A controlled regrowth and thus a controlled tuning/adjustment of defects at the regrowth interface can then in turn be used to optimize the switching speed, as a controlled (fast) non radiative recombination (NRR) process near the active region allows further reduction of the switch off time of the μ-LEDs and thus possible faster switching speeds. The idea of the invention is thus to find a good balance of emitable brightness of the-LEDs while desired switching speeds can still be provided for the respective target application.

Compared to InGaN μ-LEDs this can have the following advantages:

No piezo field in the semiconductor due to different crystal structure which could separate charge carriers and thus reduce the switching speed.

Si based detectors comprise a higher sensitivity in yellow/red emission spectrum (InGaAlP) compared to blue wavelength (InGaN).

Absorption of light in yellow/red emission spectrum (InGaAlP) compared to blue wavelength (InGaN) in an optical fiber (plastic (multicore) fibers) is reduced.

By the term “charge carrier lifetime” it is in particular to be understood the time t, until which a charge carrier within the active region recombines under the emission of light or non-radiatively. A high charge carrier lifetime comes with a high switch off time of the μ-LEDs and thus with a reduced possible switching time of the μ-LEDs, as charge carriers within the active region with a high lifetime may recombine under the emission of light well after the point in time when the μ-LEDs are already disconnected from their electrical supply. Such an “afterglow” does not allow to provide fast switching frequencies, e.g. in the GHz range.

Increasing the possibilities for recombination under the emission of light or non-radiative recombination reduces the charge carrier lifetime and at the same time increases the possibility to provide fast switching frequencies. To increase the possibilities for non-radiative recombination the edge regions of the active region adjacent to the side surfaces are contaminated with at least one of: oxygen; iron; silicon; magnesium; sulfur; tellurium; beryllium; and bor.

This can be done by controlling on the one hand a mesa etching of the semiconductor layer stack to provide the inclined side surfaces and on the other hand by controlling the regrowth process to cover the etched side surfaces with a regrowth layer. By this, the amount of defects (dangling bonds/non-radiative recombination centers) along the side surfaces, and in particular in the edge regions of the active region can be controlled to again influence the possibilities for non-radiative recombination in the active region. In particular by this the diffusion length/mean-free path of the charge carrier is limited to a central region of the active region between the edge regions in which recombination of the charge carriers under the emission of light can take place resulting in a reduced charge carrier lifetime.

According to some aspects, when viewed onto the top surface, a central region of the first charge transportation layer below the active region remains free of the first contact element. The first contact element can for example comprises the form of a ring. By this an inhomogeneous spreading of the current through the active region can be achieved since the current will seek the path of the smallest total resistance, which in most cases relates to the shortest path, and propagate along the side surfaces rather than detouring through the centre of the active region. By an optimized contact design, a current flow near the regrowth region/side surfaces can thus be promoted. In addition, this can serve to provide a light emitting window, which is free of the first contact element, through which light is emitted from the μ-LED.

The regrowth layer covering the side surfaces can for example be undoped or comprises a plurality of sublayers of a different doping type arranged in an alternating order. For example, the first regrowth layer can comprise a plurality of sublayers of n- and p-doping in an alternating order forming a npnp-barrier.

In such a case the regrowth layer may cover the side surfaces but may expose at least portions of the top surface. The regrowth layer may however also form a top contact of the μ-LED. In such a case the regrowth layer may for example be of the second doping type and covers the side surfaces as well as the top surface. The regrowth layer can for example result from a regrowth, combined with a selective area growth (SAG) mask placed on top of separate individual islands of the active region resulting from the first etching step of the epi structure on the wafer.

This is then followed by a growth of the regrowth layer. The regrowth layer can in particular be an undoped or npnp current blocking layer of high bandgap (e.g. Indium Aluminium Phosphide (InAlP)) that is grown at the island sidewalls and also areas in between the islands. The regrowth layer can however also result from a regrowth after the SAG mask of the first etching step has been removed and can include a highly conductive contact layer (Gallium Phosphide (GaP) or Gallium Arsenide (GaAs)).

According to at least one aspect, the μ-LED is a very small LED with edge lengths of less than, 20 μm, less than 10 μm or even less than 5 μm. For such small sizes, the already small lateral extensions of the active region can have a positive effect on the present invention with regard to the diffusion length/mean-free path.

According to at least one aspect, a substantially not contaminated central region of the active region between the edge regions comprises a lateral dimension between the edge regions of less than the diffusion length of the material system of the active region. By this the charge carrier lifetime can further be reduced and desired switching times for the μ-LED can be achieved.

According to at least one aspect, the μ-LED is configured to have a switching off time in the range of 0.5 ns to 10 ns, in particular a switching off time down to 0.1 ns. With such a switching off time, fast switching frequencies, e.g. in the GHz range, can be realized.

According to at least one aspect, the density of the contamination in the edge regions is between 10¹⁶ per cm³ and 10²⁰ per cm³, in particular a density between 10¹⁷ per cm³ and 10¹⁹. With such a density of the contamination a desired “number” of NRR centers can be provided in the edge regions to reduce the charge carrier lifetime to a desired level.

According to at least one aspect, the edge regions in addition comprise dislocation defects, in particular stacking faults and/or threading dislocations and/or alloy fluctuations. Such dislocation defects can be similar to the contamination result in NRR centers reducing the charge carrier lifetime in the active region.

According to at least one aspect, the μ-LED further comprises a passivation layer arranged on exposed surfaces of the regrowth layer and/or the layer stack. In particular mesa edges resulting from a second etching step to singulate several μ-LEDs can be passivated by means of the passivation layer. In this way, undesirable possible interferences along these mesa edges can be reduced/prevented.

According to a further aspect of the present invention, the μ-LED according to at least one of aforementioned aspects can be used as a means for optical data communication, in particular short distance communication of less than 10 m. The μ-LED according to at least one of aforementioned aspects can in particular be used for data transmission in large data centres and the like, to transmit data over short distances (<<10 m) for example from CPU to GPU, server to server, and/or rack to rack.

According to a further aspect of the present invention, the use of a μ-LED as a means for optical data communication, in particular short distance communication of less than 10 m, can be provided. The μ-LED comprises a semiconductor layer stack having a first charge transportation layer of a first doping type, a second charge transportation layer of a second doping type, and an active region arranged between the first and the second charge transportation layer. The semiconductor layer stack further comprises a top surface as well as side surfaces adjacent to the top surface, wherein the side surfaces are inclined with respect to a normal of the top surface. This inclination can in particular result of a first etching step of an epi structure on a wafer, to separate individual islands of the active region, which later then are each part of one optoelectronic device.

Further, the semiconductor layer stack is based on an aluminum gallium indium phosphide (InGaAlP) system. In addition, the μ-LED comprises a regrowth layer covering the side surfaces as well as a first contact element arranged on the first charge transportation layer and a second contact element electrically contacting the second charge transportation layer.

According to a further aspect of the invention, a method for manufacturing a μ-LED is provided, the method comprises the following steps:

Providing a semiconductor layer stack having a first charge transportation layer of a first doping type, a second charge transportation layer of a second doping type, and an active region arranged between the first and the second charge transportation layer;

Providing a structured mask on a top surface of the semiconductor layer stack;

Structuring the semiconductor layer stack such that the semiconductor layer stack comprises side surfaces adjacent to the top surface, wherein the side surfaces are inclined with respect to a normal of the top surface;

Regrowing a regrowth layer on the side surfaces;

Providing a first contact element on the first charge transportation layer; and

Providing a second contact element electrically contacting the second charge transportation layer;

wherein the step of structuring the semiconductor layer stack comprises contaminating edge regions of the active region adjacent to the side surfaces with at least one of:

oxygen;

iron;

silicon;

magnesium;

sulfur;

tellurium;

beryllium; and

bor.

The degree of contamination can thereby in particular be tuned by help of at least one of the following parameters:

Angle of the side surfaces with respect to the normal of the top surface;

A physical/chemical pretreatment of the layer stack and/or side surfaces; and

The epi conditions of the layer stack.

According to at least one aspect, the step of structuring the semiconductor layer stack comprises contaminating the edge regions with dislocation defects, in particular stacking faults and/or threading dislocations and/or alloy fluctuations.

According to at least one aspect, the step of contaminating is performed/tuned in such that a substantially not contaminated central region of the active region between the edge regions comprises a lateral dimension between the edge regions of less than the diffusion length of the material system of the active region.

According to at least one aspect, the step of providing the first contact element comprises, when viewed onto the top surface, leaving a central region of the first charge transportation layer below the active region free from the first contact element.

According to at least one aspect, the method further comprises a step of providing a passivation layer on exposed surfaces of the regrowth layer and/or exposed surfaces of the layer stack.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 to 3 show steps of a method for manufacturing a μ-LED in accordance with some aspects of the present invention; and

FIGS. 4 and 5 each shows a cross section of a μ-LED in accordance with some aspects of the present invention.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

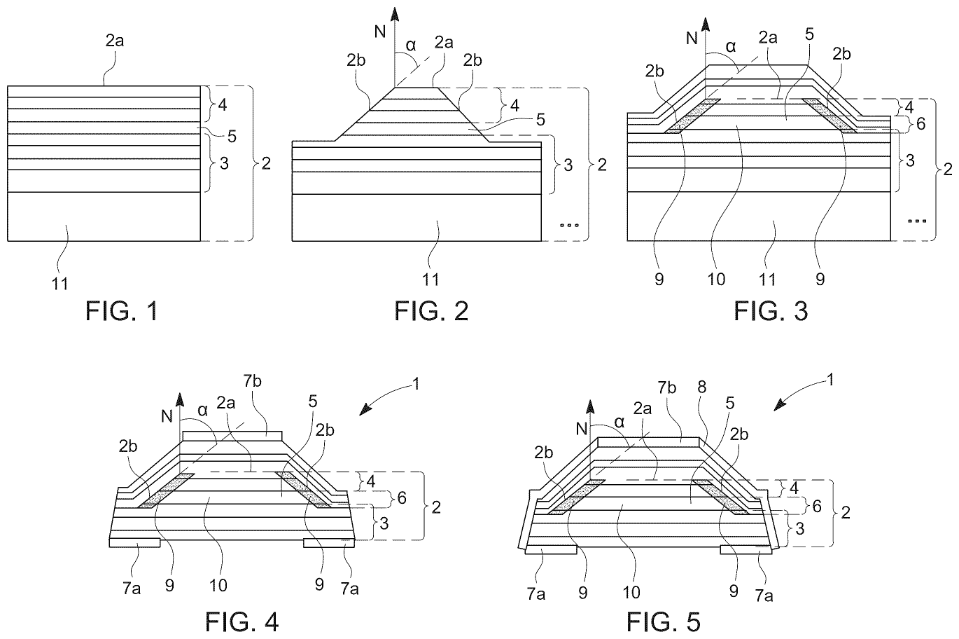

FIGS. 1 to 3 show steps of a method for manufacturing a μ-LED in accordance with some aspects of the present invention.

In a first step, as shown in FIG. 1, a layer stack 2 including a first charge transportation layer 3, an active region 5, as well as a second charge transportation layer 4 is grown on a carrier substrate 11. The first and the second charge transportation layer 3, 4 can, as shown, each comprise several sublayers to provide together with the active region 5 a layer stack 2 configured to emit light of a desired wavelength when supplied with a sufficient current. The first charge transportation layer 3 can for example comprise one or several n-doped layers, as well as one or several diffusion barrier layers adjacent to the active region 5. The second charge transportation layer 4 can on the other hand for example comprise one or several p-doped layers, as well as one or several diffusion barrier layers adjacent to the active region 5. The diffusion barrier layers can in particular be configured to prevent a diffusion of the n- or p-dopant of the n- or p-doped layers into the active region 5.

The layer stack 2 is then structured, as shown in FIG. 2, by for example providing a structured mask (not shown) on a top surface 2a of the layer stack 2 and then structuring the layer stack 2 by means of for example a first mesa etching process. Due to the structuring, separate individual islands of the active region 5 of the layer stack are separated in such that each of the individual islands of the active region 5 is bordered by inclined side surfaces 2b.

Exemplarily in FIGS. 2 and 3 only one resulting individual island of the active region 5 is shown, but by means of the “. . . ” it is to be understood that a plurality of such individual islands can be arranged next to each other on the carrier substrate 11. The layer stack 2 shown comprises a top surface 2a as well as side surfaces 2b adjacent to the top surface, wherein the side surfaces are inclined with respect to a normal N of the top surface 2a. The side surfaces 2b can for example be inclined with respect to the surface normal with an angle a of 0° to 45°, and in particular with an angle of 5° to 15°.

Then, as shown in FIG. 3, on the layer stack 2 and in particular on the side surfaces 2b, a regrowth layer 6 is grown, in particular epitaxially grown, in order to encapsulate the side surfaces 2b, and/or to provide a contact layer on the top surface 2a. In the embodiment shown, the regrowth layer 6 comprises several sublayers, in particular layers of the second doping type to provide a contact layer for the later μ-LED.

By means of a controlled etching and following regrowth step, as shown in FIGS. 2 and 3, a controlled tuning/adjustment of defects at the regrowth interface can be achieved to optimize the switching speed of the μ-LED. At least edge regions 9 of the active region 5 adjacent to the side surfaces 2b are thereby contaminated in a controlled way with at least one of: oxygen; iron; silicon; magnesium; sulfur; tellurium; beryllium; and bor. The contamination of the edge region results in NRR centers, the amount of which can be tuned by means of the controllable process. When operating the μ-LED, a controlled (fast) non radiative recombination (NRR) process near the active region 5 is thus achievable and allows a reduction of the switch off time of the μ-LED and thus faster switching speeds are possible. The idea of the invention is thus to find a good balance of emitable brightness of the μ-LEDs while desired switching speeds can still be provided for the respective target application.

The μ-LED as a whole is also structured due to a second mesa etching process (not shown) to optically and electrically isolate several μ-LEDs, whereas in comparison to the first mesa etching process the resulting side surfaces/mesa edges do not comprise portions of the active region 5.

FIGS. 4 and 5 each show a cross section of a μ-LED 1 in accordance with some aspects of the present invention. The μ-LED 1 each comprises a layer stack 2, in particular semiconductor layer stack, having a first charge transportation layer 3 of a first doping type, a second charge transportation layer 4 of a second doping type, an active region 5 arranged between the first and the second charge transportation layer. The carrier substrate 11, as shown for the manufacturing steps in FIGS. 1 to 3 as well as a portion of the first charge transportation layer 3 has compared to FIGS. 1 to 3 however been removed.

The layer stack 2 comprises a top surface 2a as well as side surfaces 2b adjacent to the top surface, wherein the side surfaces 2b are inclined with respect to a normal N of the top surface 2a. This inclination can in particular result of the first etching step, shown in FIG. 2. The optoelectronic device 1 further comprises a regrowth layer 6 covering the side surfaces 2b and the top surface 2a forming a contact layer for the μ-LED 1. In addition, a first contact element is 7a arranged on the first charge transportation layer 3 and a second contact element 7b, electrically contacting the second charge transportation layer 4, is arranged on the regrowth layer 6. To provide the electrically contacting, the regrowth layer 6 is an at least partially conductive layer and in particular a semiconductor layer or arrangement of several semiconductor layers of the second doping type.

The first contact element za is formed such that, when viewed onto the top surface 2a, a central region of the first charge transportation layer 3 below the active region 5 remains free of the first contact element 7a. This can in particular be the case for the first contact element 7a having the form of a ring arranged on the first charge transportation layer 3. By this an inhomogeneous spreading of the current through the active region 5 can be achieved since the current will seek the path of the smallest total resistance, which in most cases relates to the shortest path, and propagate along the side surfaces 2b through the edge regions 9 rather than detouring through the centre 10 of the active region 5.

In addition to the embodiment shown in FIG. 4, the μ-LED 1 shown in FIG. 5 further comprises a passivation layer 8 arranged on exposed surfaces of the regrowth layer 6 and exposed side surfaces (resulting from the second etching step to singulate several μ-LEDs) of the layer stack 2. In particular mesa edges resulting from the second etching step to singulate several μ-LEDs can be passivated by means of the passivation layer 8. In this way, undesirable possible interferences along these mesa edges can be reduced/prevented.

1.-15. (canceled)

16. A μ-LED comprising:
a semiconductor layer stack having a first charge transportation layer of a first doping type, a second charge transportation layer of a second doping type, and an active region arranged between the first and second charge transportation layers,
wherein the semiconductor layer stack comprises a top surface as well as side surfaces adjacent to the top surface,
wherein the side surfaces are inclined with respect to a normal of the top surface, and
wherein the semiconductor layer stack is based on an aluminum gallium indium phosphide system;
a regrowth layer covering the side surfaces; and
a first contact element arranged on the first charge transportation layer and a second contact element electrically contacting the second charge transportation layer,
wherein edge regions of the active region adjacent to the side surfaces are contaminated with at least one of oxygen, iron, silicon, magnesium, sulfur, tellurium, beryllium, or bor.

17. The μ-LED according to claim 16, wherein, when viewed from the top surface, a central region of the first charge transportation layer below the active region remains free of the first contact element.

18. The μ-LED according to claim 17, wherein the first contact element comprises a form of a ring.

19. The μ-LED according to claim 16, wherein a substantially not contaminated central region of the active region between the edge regions comprises a lateral dimension between the edge regions of less than a diffusion length of the material system of the active region.

20. The μ-LED according to claim 16, wherein the μ-LED is configured to have a switching off time in a range of 0.1 ns to 10 ns.

21. The μ-LED according to claim 16, wherein a density of the contamination in the edge regions is between 10¹⁶ per cm³ and 10²⁰ per cm³.

22. The μ-LED according to claim 16, wherein the edge regions further comprise dislocation defects.

23. The μ-LED according to claim 16, wherein the edge regions further comprise stacking faults and/or threading dislocations and/or alloy fluctuations.

24. The μ-LED according to claim 16, further comprising a passivation layer arranged on exposed surfaces of the regrowth layer and/or exposed surfaces of the layer stack.

25. An optical data communication device comprising:
the μ-LED according to claim 16,
wherein the optical data communication device is configured for communicating over a distance of less than 10 m.

26. An optical data communication device comprising:
a semiconductor layer stack having a first charge transportation layer of a first doping type, a second charge transportation layer of a second doping type, and an active region arranged between the first and the second charge transportation layer,
wherein the semiconductor layer stack comprises a top surface as well as side surfaces adjacent to the top surface,
wherein the side surfaces are inclined with respect to a normal of the top surface, and wherein the semiconductor layer stack is based on an aluminum gallium indium phosphide system;
a regrowth layer covering the side surfaces; and
a first contact element arranged on the first charge transportation layer and a second contact element electrically contacting the second charge transportation layer, wherein the optical data communication device is configured for communicating over a distance of less than 10 m.

27. A method for manufacturing a μ-LED, the method comprising:
providing a semiconductor layer stack having a first charge transportation layer of a first doping type, a second charge transportation layer of a second doping type, and an active region arranged between the first and the second charge transportation layer;
providing a structured mask on a top surface of the semiconductor layer stack;
structuring the semiconductor layer stack such that the semiconductor layer stack comprises side surfaces adjacent to the top surface, wherein the side surfaces are inclined with respect to a normal of the top surface;
re-growing a regrowth layer on the side surfaces;
providing a first contact element on the first charge transportation layer; and
providing a second contact element electrically contacting the second charge transportation layer,
wherein structuring the semiconductor layer stack comprises contaminating edge regions of the active region adjacent to the side surfaces with at least one of oxygen, iron, silicon, magnesium, sulfur, tellurium, beryllium, or bor.

28. The method according to claim 27, wherein structuring the semiconductor layer stack comprises contaminating the edge regions with dislocation.

29. The method according to claim 27, wherein structuring the semiconductor layer stack comprises contaminating the edge regions with stacking faults and/or threading dislocations and/or alloy fluctuations.

30. The method according to claim 27, wherein contaminating is performed such that a substantially not contaminated central region of the active region between the edge regions comprises a lateral dimension between the edge regions of less than a diffusion length of the material system of the active region.

31. The method according to claim 27, wherein providing the first contact element comprises leaving a central region of the first charge transportation layer below the active region free from the first contact element when viewed from the top surface.

32. The method according to claim 27, further comprising providing a passivation layer on exposed surfaces of the regrowth layer and/or exposed surfaces of the layer stack.
